(19) United States
(12) Patent Application Publication
(10) Pub. No.: US 2015/0329960 A1
(43) Pub. Date: Nov. 19, 2015

(54) CORROSION RESISTANT OBJECT WITH ALLOYING ZONE

(71) Applicant: Danfoss A/S Tantalum Technologies, Nordborg (DK)

(72) Inventors: Bo Gillesberg, Augustenborg (DK); Soeren Eriksen, Roskilde (DK)

(21) Appl. No.: 14/811,009

(22) Filed: Jul. 28, 2015

Related U.S. Application Data
(63) Continuation-in-part of application No. 12/918,643, filed on Oct. 8, 2010.

(30) Foreign Application Priority Data
Feb. 28, 2008 (DK) PA 2008 00291

(51) Int. Cl. C23C 16/14; B32B 15/01; C23C 16/44; C23C 16/56; C23C 16/02; C23C 16/455

(52) U.S. Cl. CPC C23C 16/14; C23C 16/0209; C23C 16/455; C23C 16/4401; C23C 16/56; B32B 15/01

(57) ABSTRACT

This invention relates to objects having a corrosion resistant surface improving the overall corrosion resistance of the object relative to the core material, preferably being titanium or titanium based. The surface layer preferably contains at least 80% by mass of a refractory metal such as tantalum, or an alloy based on one or more refractory metals, To ensure a good adhering of the surface to the base material an alloy layer is created between a core element and the surface layer having a thickness at least twice that of the surface layer, where the alloy layer itself has corrosion resistant properties.

### CROSS-REFERENCE TO RELATED APPLICATIONS

This application is a continuation-in-part of U.S. application Ser. No. 12/918,643, filed Oct. 8, 2010, which is the National Stage of International Patent Application No. PCT/DK2009/000052 filed on Feb. 26, 2009, which claims priority to Danish Patent Application No. PA 2008 00291 filed Feb. 28, 2008, the contents of which are incorporated by reference.

### TECHNICAL FIELD

This invention relates to objects having a corrosion resistant surface improving the overall corrosion resistance of the object relative to the core material, preferably being titanium or titanium based. The surface layer preferably contains at least 80% by mass of a refractory metal such as tantalum, or an alloy based on one or more refractory metals. To ensure a good adhering of the surface to the base material an alloy layer is created between a core element and the surface layer having a thickness at least twice that of the surface layer, where the alloy layer itself has corrosion resistant properties.

### BACKGROUND

Objects which are meant to be positioned in highly corrosive environments must have an outer surface which is corrosion resistant in order to protect the object. Such a corrosion resistant outer surface may be provided by manufacturing the entire object from a corrosion resistant material. This may, however, be undesirable, e.g. due to the costs involved in manufacturing such an object, or because the corrosion resistant material may fail to meet other requirements or properties which the object has to fulfil or have, e.g. in terms of strength, magnetic properties, flexibility, durability, density, weight, thermal or electrical conductivity, workability (e.g. with respect to pressing, stamping, welding, forging, screwing, soldering or gluing), elasticity, fatigue properties, lubrication related properties, hardness, roughness, etc. Accordingly, a corrosion resistant outer surface is often provided by coating the object with a layer of corrosion resistant material, such as tantalum (Ta), Niobium (Nb), zirconium (Zr), Tungsten (W), Titanium (Ti) or alloys, that includes one or more of these materials in a concentration of at least 10% by mass.

It is vital that such a surface layer is tight without pinholes creating exposed spots of the object under the coating to the highly corrosive environments, and a number of documents describes methods to apply such a pinhole free layer, such as EP0578605B1 describing a molten bath for plating with high-melting metals, in particular niobium and tantalum. The bath consists of an alkali metal fluoride melt, which contains oxide ions and ions of the metal to be precipitated. The molar ratio between the metal to be precipitated and the oxide ions, or the other cations in the melt, must be held within given ratios. The redox level must be held at a value which corresponds to that which is reached when the molten bath is in contact with the particular high-melting metal in the metallic form.

### SUMMARY

A first object of the invention is to ensure good attachment to a base material and mechanical performances of the surface layer. This is ensured by the formation of a diffusion zone, or alloying zone. This alloying zone ensures that the resistant surface is sufficiently ductile to let the surface, or the whole object, being mechanically modified without creating cracks or other weaknesses undermining or damaging the corrosion resistance. The base material preferably but not limiting is titanium or titanium based.

A further object of the invention is to ensure that the alloying zone itself has corrosion resistant properties and, should the surface layer or coating fail due to damage, wear, slow corrosion, then to give means for estimating the corrosion speed, and thereby the remaining life time of the object, given the corrosion environment. This is ensured by the alloying zone being thick in relation to the thickness of the surface layer or coating and where the content of the main substance, or the corrosion resistant material, of the surface layer (like Ta) decreases into the alloying zone, so that the corrosion resistance decreases into the alloying zone.

The thickness of the surface layer is defined as the thickness from the surface to where the concentration of the corrosion resistant material is reduced to 90% by mass of the total concentration of the surface layer. The alloying zone is defined to begin at this 90% limit. The thickness of the alloying zone is defined as the thickness from the beginning of the alloying zone at the 90% limit, to the depth where the concentration of the corrosion resistant material is reduced to 10% by mass of the concentration at the 90% limit. At that point the total concentration of the corrosion resistant material is 9% by mass. An alternative definition of the depth of the alloying zone is the depth from the beginning of the alloying zone at the 90% limit to the point where the total concentration of the corrosion resistant material is down to 20% by mass, averaged over the depth.

Typically half of the deposited tantalum is alloyed into the material, giving an alloying zone 2-3 times the thickness of the corrosion resistant surface layer. For example, the object may have a 10 micrometers surface layer and a 25 micrometers alloying zone.

If the surface layer has been damaged or even removed by wear or slow corrosion, the alloying zone having better corrosion resistance than the base material still offers some protection, giving rise to only slow corrosion attack. From a measurement of the content of the corrosion resistant material in the actual surface, the corrosion speed and hence the remaining service life may be predicted (given a known corrosion environment).

The alloying zone and the surface layer are preferably formed by a CVD process. In a CVD process of formation of the alloying zone and the surface layer, the deposition process is conducted continuously without interruption for sufficient time to create an alloying zone at least twice the thickness of the surface layer.

### BRIEF DESCRIPTION OF DRAWINGS

FIG. 1 The object of the invention showing a base material with a surface layer and an alloying zone there between.

FIG. 2 The object of the invention where the surface layer and part of the alloying zone have been removed.

FIG. 3 A first micrograph of a cross-section of the preferred object of the invention in which the base material is titanium and the surface layer is tantalum.

FIG. 4 A second micrograph of a cross-section of the preferred object of the invention in which the base material is titanium and the surface layer is tantalum.

FIG. 5 A third micrograph of a cross-section of the preferred object of the invention in which the base material is titanium and the surface layer is tantalum.

### DETAILED DESCRIPTION

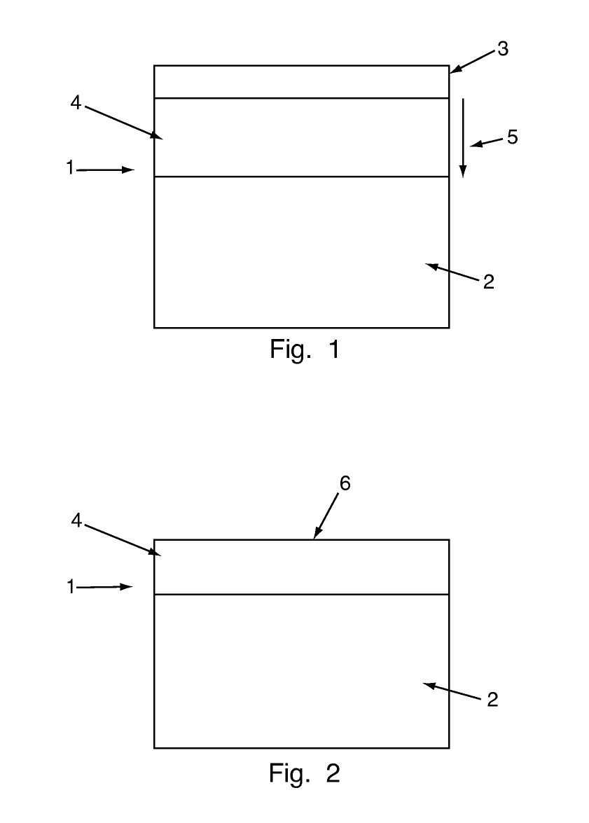

FIG. 1 illustrates the object (1) of the invention having a base element (2) being of a titanium based material. The object has a corrosion firm surface layer (3) comprising a concentration of at least 80% by mass of a corrosion resistant material like Ta, Nb, W, Ti, or other refractory metals. The thickness of the surface layer is defined as the thickness from the surface to where the concentration of the corrosion resistant material (like Ta or Ti) is 90% by mass of the total concentration of the surface layer, where the alloying zone is defined to begin.

An alloying zone (4) is formed between the base element (2) and the surface layer (3) with a decreasing concentration of the corrosion resistant material into the object, being illustrated by the direction of arrow (5). The thickness of the alloying zone is defined as the thickness from the beginning of the alloying zone, to the depth where the concentration has fallen to 10% by mass of the concentration at the beginning of the zone.

FIG. 2 illustrates the object after a graduated decrease of the corrosion firmness into the deposit, meaning that the coating (3), or surface layer, has been damaged, removed by wear or slow corrosion, giving a slow corrosion attack that also has removed part of the alloying zone (4).

These lowered corrosion abilities reflect the composition of the actual surface (6) of the object (1), being gradually changed into the alloying zone having a decreasing concentration of the corrosion resistant material. From a measurement of the content of the corrosion resistant material in the actual surface (6), then the corrosion speed, or the remaining service life, may be predicted (given a known corrosion environment).

A sample of the preferred object of the invention was prepared by the following process. The titanium base material was placed in a 10L CVD vessel and heated to 900° C. under a vacuum of 10⁻² mbar. While being maintained at a temperature of 900° C., the vessel was then subjected to a flow of hydrogen gas to a pressure of 25 mbar and a flow rate of 13.5 mol/h for 5 minutes (“first period of time”). The vessel was then again evacuated to a vacuum of 10⁻² mbar, following which tantalum pentachloride at a flow rate of 0.135 mol/h and argon gas at a flow rate of 0.27 mol/h were admitted to the vessel for 4 minutes (“second period of time”). Hydrogen gas at a flow rate of 13.5 mol/h was then added to the flow of tantalum pentachloride and argon gas and the combination of three gasses continued for a further 75 minutes (“third period of time”). The flow of gasses was then discontinued, and the vessel was maintained at 900° C. under a vacuum of 10⁻² mbar for 30 minutes (“fourth period of time”), after which the vessel was cooled to ambient temperature under a vacuum of 10⁻² mbar.

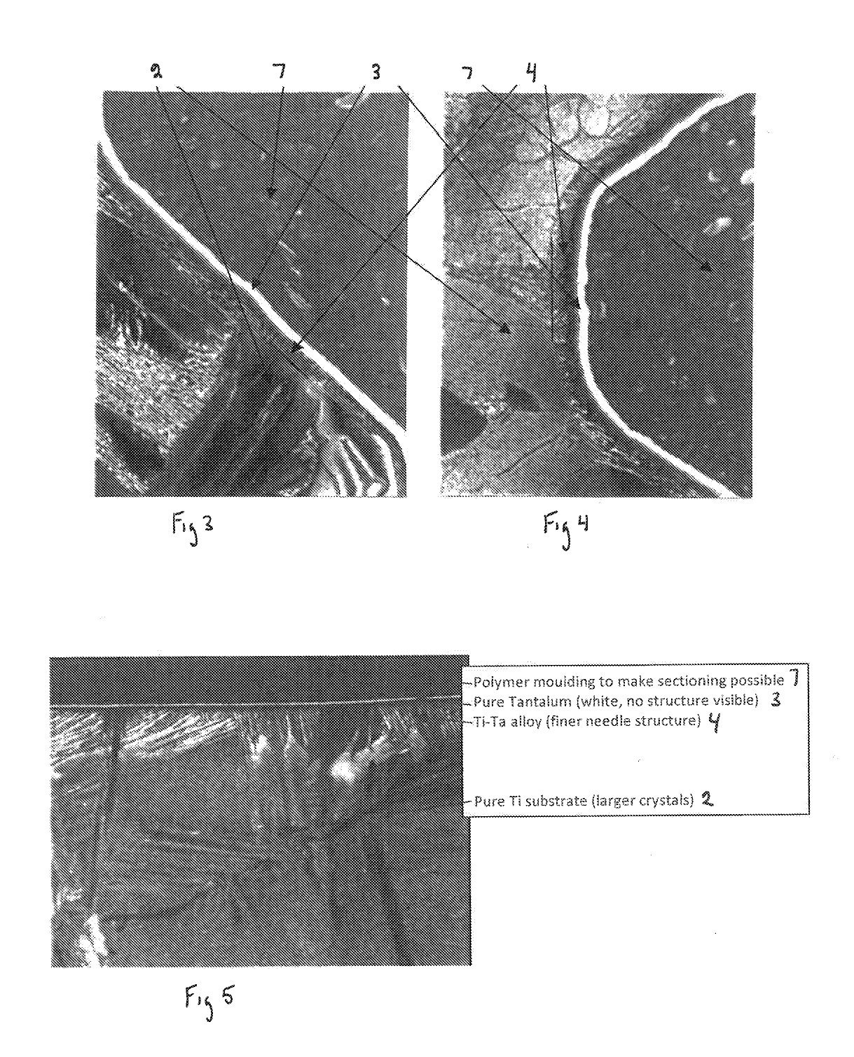

The structure of the resulting object is shown in FIGS. 3-4. The object has base element (2) of titanium and a corrosion firm surface layer (3) of tantalum. The alloying zone (4) is formed between the titanium base layer and the tantalum surface layer. In order to prepare the sample for the micrograph, the surface of the object is coated with a polymer moulding material (7). In FIGS. 3 and 4, the extent of the alloying zone (4) is marked by the black line parallel to the tantalum surface at the end of the arrows (4).

FIG. 5 shows the structure of an object made by a similar process but with tantalum pentachloride at a flow rate of 0.7 mol/h, argon gas at a flow rate of 0.5 mol/h and hydrogen gas at a flow rate of 20 mol/h and with a third period of time of 60 minutes. The Figure shows the 4 micrometer thin white layer of pure tantalum (3) and the wide alloy zone (4) beneath the tantalum layer (3) having the fine needle structure and having a thickness several times the thickness of the tantalum layer (3).

Surprisingly, it has been found that if titanium is heated to a temperature of at least 880° C. (and preferably at least 900° C.), its crystal structure becomes compatible with the crystal structure of tantalum and the two materials can mix to form the alloying zone, resulting in a tight bond between the two metals. At temperatures below 880° C. (such as 825° C.), however, the crystal structure of titanium remains incompatible with the crystal structure of tantalum, and the tight bond does not form, resulting in delamination and the tantalum layer flaking off the titanium. The temperature can be any temperature above 880° C. that is convenient, such as up to 1000° C. or 1250° C., but no particular advantage is derived from temperatures higher than about 900° C., which temperature is used in order to be well above the critical temperature.

Applicants have also surprisingly discovered that the order of gas flow is important in the process of preparing the preferred object of the invention. The heated titanium is first subjected to a flow of hydrogen gas. After the flow of hydrogen gas is stopped, tantalum pentachloride and argon are introduced and, after a few minutes, the flow of hydrogen is resumed. If the titanium is subjected initially to hydrogen and tantalum pentachloride, imperfections arise in the surface that are not observed in the present process. The initial flow of hydrogen assists the transition of the crystal structure of the titanium to one that is compatible with the crystal structure of tantalum. Applicants have found that five minutes at a flow of 13.5 mol/h is sufficient, but the flow rate and time may be altered as would be understood by those of skill in the art. It is important (after the initial flow of hydrogen is stopped) to subject the titanium to a flow of tantalum pentachloride and argon before any hydrogen flow is resumed. Applicants have found that a period of tantalum pentachloride and argon flow of four minutes before resuming hydrogen flow is sufficient, but one of skill in the metallurgy art could adjust the time. The period of flow of tantalum pentachloride, argon, and hydrogen (third period of time) may be varied as is recognized by those of skill in the art depending on the thickness of the tantalum layer and alloy zone desired. For example, times between 60 and 360 minutes could be used and even as long as 4 hours. Similarly, the time after discontinuation of gas flow (fourth period of time) may also be varied from 15 to 90 minutes depending on the thickness of the titanium base material so as to allow any hydrogen dissolved in the tantalum, alloy zone, and titanium to escape.

Those of skill in the art will appreciate that many variations are possible within the scope of the appended claims. Thus, while the disclosure is particularly shown and described above, it will be understood that changes in form and detail may be made without departing from the scope of the claims.

1. An object having a base element, a corrosion resistant layer having a surface and comprising a corrosion resistant material and having a first thickness defined as the thickness of the corrosion resistant layer from the surface to a location where the concentration of the corrosion resistant material is reduced to 90% by mass of the concentration of the corrosion resistant material at the surface, this location being the beginning of an alloying zone having a second thickness defined as the thickness from the beginning of the alloying zone, to the depth where the concentration of the corrosion resistant material is reduced to 10% by mass of the concentration at the beginning of the alloying zone, wherein the second thickness is at least two times that of the first thickness and wherein the corrosion resistant layer is tight and free of pinholes.

2. The object according to claim 1, wherein the base element is a titanium based material.

3. The object according to claim 1 wherein the corrosion resistant layer comprises a refractory metal.

4. The object according to claim 3, wherein the corrosion resistant layer has a concentration of at least 80% by mass of refractory metal.

5. The object of claim 3 wherein the refractory metal is tantalum, niobium, or tungsten.

6. The object according to claim 5 wherein the corrosion resistant layer has a concentration of at least 80% by mass of refractory metal.

7. An object having, in order, a coating having a surface and a first thickness, an alloy zone having a second thickness, and a base element, the coating comprising a corrosion resistant material with a concentration of 100% by mass at the surface of the coating and a concentration of 90% by mass where the coating contacts the alloy zone and being tight and free of pinholes, the alloy zone having a concentration of corrosion resistant material of 90% by mass where the alloy zone contacts the coating and a concentration of corrosion resistant material of 9% by mass where the alloy zone contacts the base element, the second thickness being at least two times the first thickness.

8. The object according to claim 3 wherein the base element is titanium and the corrosion resistant layer is tantalum.

9. The object according to claim 7 wherein the base element is titanium and the corrosion resistant layer is tantalum.

10. The object according to claim 1 which is made by the process comprising the steps of:
a) heating titanium to a temperature of at least 880° C. under vacuum in a CVD vessel and maintaining that temperature throughout the process;
b) introducing a flow of hydrogen gas into the CVD vessel for a first period of time;
c) stopping the flow of hydrogen gas;
d) introducing a flow of tantalum pentachloride and argon into the CVD vessel for a second period of time;
e) adding a flow of hydrogen to the flow of tantalum pentachloride and argon into the CVD vessel for a third period of time;
f) stopping the flow of all gasses and maintaining the titanium at a temperature of at least 880° C. under vacuum for a fourth period of time; and
g) allowing the titanium to cool to ambient temperature under vacuum.

11. A process for making a corrosion resistant object comprising the steps of:
a) heating titanium to a temperature of at least 880° C. under vacuum in a CVD vessel and maintaining that temperature throughout the process;
b) introducing a flow of hydrogen gas into the CVD vessel for a first period of time;
c) stopping the flow of hydrogen gas;
d) introducing a flow of tantalum pentachloride and argon into the CVD vessel for a second period of time;
e) adding a flow of hydrogen to the flow of tantalum pentachloride and argon into the CVD vessel for a third period of time to produce a tantalum surface layer and a tantalum/titanium alloy zone;
f) stopping the flow of all gasses and maintaining the titanium at a temperature of at least 880° C. under vacuum for a fourth period of time; and
g) allowing the tantalum coated titanium to cool to ambient temperature under vacuum.

12. The process of claim 11 wherein the temperature throughout the process is 900° C.

13. The process of claim 12 wherein the second period of time is about four minutes.

14. The process of claim 13 wherein the third period of time is from about 60 to about 360 minutes.

15. The process of claim 14 wherein the fourth period of time is from about 15 to about 90 minutes.
